(19) United States
(12) Patent Application Publication
(10) Pub. No.: US 2026/0020181 A1
(43) Pub. Date: Jan. 15, 2026

(54) MACHINE ROOM HVAC ENCLOSURE

(71) Applicant: RF INDUSTRIES, LTD., San Diego, CA (US)

(72) Inventors: Richard De Felice, North Kingstown, RI (US); David Therrien, North Kingstown, RI (US); Dino Giordano, North Kingstown, RI (US); Ken Tobin, North Kingston, RI (US)

(21) Appl. No.: 19/263,814

(22) Filed: Jul. 9, 2025

Related U.S. Application Data
(60) Provisional application No. 63/669,057, filed on Jul. 9, 2024.

(51) Int. Cl. H05K 7/20

(52) U.S. Cl. CPC H05K 7/20181

(57) ABSTRACT

A cabinet device for ventilation equipment includes a self-contained modular unit adapted for mounting in a cutout on a wall or door of a machine room enclosure, typically small, standalone confined structures used for telecommunications and related equipment, often in conjunction with a site structure such as a cell tower or antenna. Weather resistance is provided by a series of baffles, gasketing and directed intake and output conduits, specifically intended to prevent water infiltration. Fans direct airflow through the intake and output conduits for maintaining temperature inside the enclosure through a controlled exchange of ambient air, often in conjunction with native HVAC (Heating, Ventilation and Air Conditioning) equipment when the outside temperature limits the effectiveness of ambient air exchanges. An inwardly hinged panel supports the fans and allows access for air filter access and maintenance, without removal or breach of the weathertight engagement with the enclosure exterior.

### RELATED APPLICATIONS

This patent application claims the benefit under 35 U.S.C. § 119 (e) of U.S. Provisional Patent App. No. 63/669,057, filed Jul. 9, 2024, entitled “MACHINE ROOM HVAC ENCLOSURE,” incorporated herein by reference in entirety.

### BACKGROUND

Computing resources are widely distributed throughout the telecommunications industry. Proliferation of personal electronic devices continues to increase the need for both wireless and wired network connectivity. Modern network deployment requires connectivity hardware, such as cell towers and antennas, in addition to more substantial data centers, to be located throughout a region supported by the network. Each of these locations requires an environmentally controlled equipment enclosure to operate effectively. Further, since the equipment enclosures are typically unstaffed, reliability and longevity of cooling appliances and other HVAC (Heating, Ventilation and Air Conditioning) apparatus is paramount.

### SUMMARY

An enclosure cabinet device for ventilation equipment includes a self-contained modular unit adapted for mounting in a cutout on a wall or door of a machine room enclosure, typically small, standalone confined structures used for telecommunications and related equipment, often in conjunction with a site structure such as a cell tower or antenna. Weather resistance is provided by a series of baffles, gasketing and directed intake and output conduits, specifically intended to prevent water infiltration. Fans direct airflow through the intake and output conduits for maintaining temperature inside the enclosure through a controlled exchange of ambient air, often in conjunction with native HVAC equipment when the outside temperature limits the effectiveness of the ambient air exchanges. An inwardly hinged panel supports the fans and allows access for air filter access and maintenance, without removal or breach of the weathertight engagement with the enclosure exterior.

Machine room enclosures, or simply machine rooms, are a temperature controlled, weathertight environment suited for operational performance and longevity of computers and electronic equipment including telecommunications equipment such as base stations, routers, ethernet switches, and the like. They need not maintain temperatures for human comfort (around 70°-75° F.), but rather may be afforded greater temperature ranges. The equipment in machine rooms often generate substantial heat, therefore air conditioner cooling is often a significant component of temperature control. When ambient temperatures permit, ventilation with ambient outside air can provide adequate cooling while avoiding the energy consumption of an AC unit, such as that described in U.S. Pat. No. 8,313,038, filed Jun. 25, 2008, entitled “TELECOM SHELTER COOLING AND CONTROL SYSTEM,” incorporated herein by reference.

Configurations herein are based, in part, on the observation that such a system provides direct air control (DAC) for thermostatically controlled ambient air exchange when outside air exchanges can achieve adequate cooling without powering an AC compressor and heat exchanger. Unfortunately, conventional approaches to installation or retrofitting of ambient air exchange systems suffer from the shortcoming that an additional fenestration in the machine room is required for passing the DAC system through the wall. Additional fenestrations present opportunities for weather infiltration, and further can complicate maintenance procedures when the conventional DAC system needs to be opened for filter changeovers, cleaning and maintenance.

Accordingly, configurations herein substantially overcome the shortcomings of conventional HVAC alternatives by providing a permanent, exterior sealed DAC enclosure that employs a single hinged interior panel for filter access and which provides a sealed, NEMA-4 (National Electric Manufacturers Association) enclosure when the hinged panel is secured.

In further detail, configurations herein depict

### BRIEF DESCRIPTION OF THE DRAWINGS

The foregoing and other objects, features and advantages of the invention will be apparent from the following description of particular embodiments of the invention, as illustrated in the accompanying drawings in which like reference characters refer to the same parts throughout the different views. The drawings are not necessarily to scale, emphasis instead being placed upon illustrating the principles of the invention.

FIG. 1 is a perspective view of the cabinet for mounting on an enclosure for telecommunications or electronic, heat sensitive equipment;

FIGS. 2A-2D show a sequence for servicing the cabinet of FIG. 1;

FIG. 3 shows the device of FIGS. 1 and 2 deployed on an enclosure;

FIGS. 4A-4B shows a door mounting of the device of FIGS. 1-2D;

FIG. 5 shows servicing of the device of FIGS. 1-4B in a door mount context; and

FIG. 6 shows test data from an ambient air exchange in an enclosure using the device of FIGS. 1-5.

### DETAILED DESCRIPTION

An example configuration of a device for weatherproof ambient air exchange in a machine room enclosure is disclosed below. Configurations herein are particularly amenable to a retrofitting of existing enclosures because only a very small clearance into the enclosure is needed and because the additional fenestration on the enclosure is weathertight as maintenance access is facilitated from within the enclosure. No exterior facing panels or hatch openings need to be accessed for maintenance access such as filter changes.

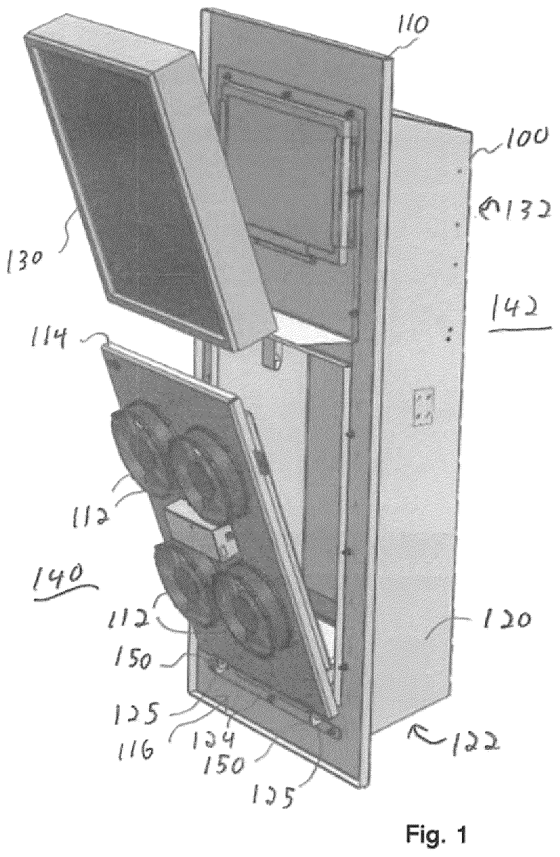

FIG. 1 is a perspective view of the cabinet for mounting on an enclosure for telecommunications or electronic, heat sensitive equipment. In a machine room enclosure for remote housing of environmentally sensitive electronic equipment, the enclosure device encapsulates an ambient air exchange apparatus through an exterior surface of the enclosure which exchanges ambient air with the machine room interior for controlling the temperature of the machine room. Referring to FIG. 1, the device includes a cabinet 100 having a weathertight exterior, and a flange 110 around a perimeter of the cabinet. At least one fan 112 (4 shown) attaches to a hinged surface 114 on an interior surface 116 of the enclosure. The hinged surface 114 is adapted to pivot outward from the cabinet 100 for access to a filter 130 between the fan 112 and an exterior air input passage 120. A downward facing air inlet 122 is in communication with the input air passage 120.

The full hinged surface 114 and fan assembly rests on a self-aligning hinge 150 along a lower edge 124 of the hinged surface 114, such that the self-aligning hinge 150 is adapted to support the hinged surface 114 for filter 130 access when in an open position. The hinge 150 is also adapted to engage the hinged surface 114 in a sealing engagement with the cabinet 100 when in a closed position, which provides weathertight operation of the cabinet for ambient air exchange.

The self-aligning hinge 150 (2 shown, more may be employed) forms a pivoting engagement of the hinged surface 114 with the cabinet 100 along the lower edge 124 of the hinged surface 114, and further includes a protrusion 125, such that the protrusion 125 forms an interference fit with the cabinet 100 when the hinged surface 114 is in the open position. The protrusion 125 extends from the hinged surface and bears on a surface of the cabinet 100 when the hinged surface is open sufficiently (between 20° and 40° from vertical) to afford access to the filter 130. Once closed, the cabinet 100 maintains a weathertight engagement with the enclosure according to a NEMA-4 (National Electric Manufacturers Association) criteria, as the exterior surface of the cabinet 100 has no pivoting/hinged openings or access points that can compromise weathertightness.

Airflow through the cabinet 100 is provided by an air outlet 132 formed from a passage through the enclosure for passage of an airflow from an interior 140 of the enclosure to the ambient environment 142. The passage employs a series of baffles and/or shields configured for preventing water infiltration while permitting air exhaust from the enclosure 100.

In an example configuration, the hinged surface 114 incorporates operating electronics, memory and control for a direct air control (DAC) circuit, such that the DAC circuit is configured for temperature based operation of the fan 112 based on a temperature difference between ambient air outside 142 the enclosure and machine room air 140 within the enclosure.

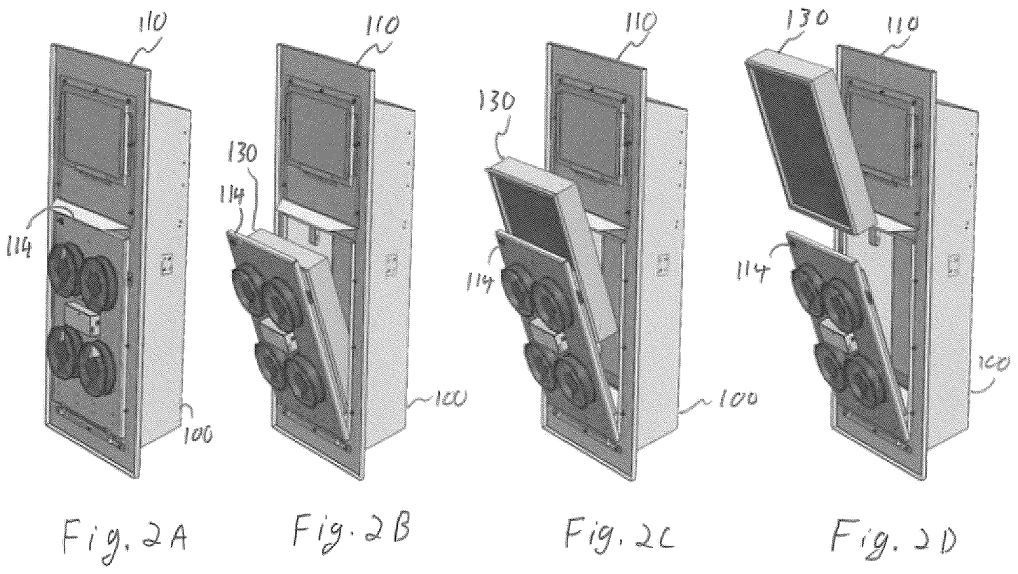

FIGS. 2A-2D show a sequence for servicing the cabinet of FIG. 1. Ventilation equipment such as the disclosed device may be unattended and periodically serviced by deployed technicians. An air filter 130 maintains clean, particle free air within the enclosure, but requires periodic maintenance and cleaning or replacement. The hinged surface, normally in sealed communication with the cabinet 100 to maintain fan driven airflow, may be open as in FIG. 2B along the hinged lower edge 124 pivoting against the lower run of the flange 110. The hinged surface 114 remains in contact with the cabinet via the hinges 150, while an upper edge opens to allow the filter 130 to be removed, as shown in FIG. 2C. Once completely removed, as in FIG. 2D, the filter 130 is cleaned or replaced and the hinged surface 114 again closed as in FIG. 2A.

Since the hinged surface 114 opens on an interior facing surface (interior wall or interior side of a door), the cabinet 100 maintains a fixed, weathertight engagement with the enclosure. The only ingress points into the enclosure are via the air inlet, which faces downward from the cabinet, and the hinge 150 along the lower edge 124 which forms a downward facing opening, lip or overlapping seam which is further protected from the cabinet 100 and preferably is disposed above a lower edge of the air inlet 122, Restating, the installed cabinet provides only downward facing openings shielded by the cabinet 100, thus having no exposed discontinuities in the exterior cabinet 100 surface which could be infiltrated by downward or even horizontal bursts of rain or snow.

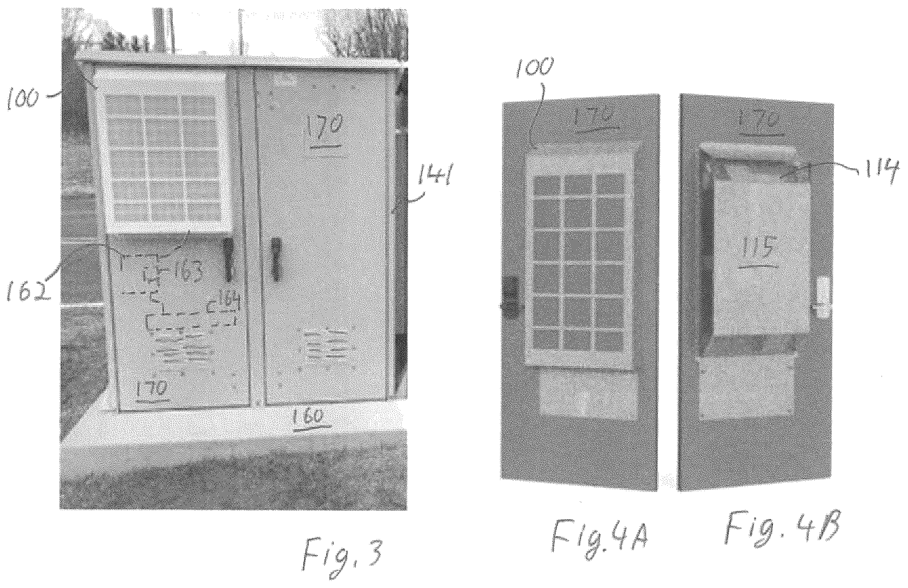

FIG. 3 shows the device of FIGS. 1 and 2 deployed on an enclosure 141. A typical enclosure 141 may be an unremarkable utilitarian structure deployed on a concrete pad 160, and the cabinet 100 mounted on a door 170 or any surface of the enclosure 141. Installation typically includes a controller 162 configured for activating the fans 112 for exchanging ambient outside air with an air volume in the enclosure 141 based on a temperature of the ambient outside air being cooler than an interior of the enclosure. While direct air control (DAC) may be used for heating or cooling, depending on the ambient air temperature, the most frequent scenario is exchanging ambient outside air with an air volume in the enclosure based on a temperature of the ambient outside air being cooler than the interior of the enclosure 141, in effect replacing the need for compressor cooling by exchanging cooler ambient air 142.

The device may be installed in a standalone configuration, relying only on ambient air exchange, or may also employ an HVAC (Heating Ventilation Air Conditioning) interface 163, such as in a retrofit arrangement where the DAC capability is added to an existing HVAC cooled enclosure for more economical operation. The retrofitted DAC is a versatile solution designed to integrate seamlessly with existing HVAC systems. When the temperature inside the enclosure is below the maximum allowable threshold, the device recirculates air to maintain the temperature. If the temperature exceeds the threshold, the fans 112 introduce fresh, filtered ambient air. This DC-powered, NEMA 4-rated solution ensures continuous operation during power outages, reduces operational expenses by significantly lowering HVAC operation and power consumption, and decreases HVAC replacement and maintenance costs, extending the lifespan of HVAC systems.

In such a retrofit integration, the HVAC interface 163 is responsive to the controller 162 for deactivating a native air conditioning compressor when a temperature difference between the ambient outside air with an air volume in the enclosure provides a temperature range suitable for equipment within the enclosure. The HVAC interface 163 is again invoked for activating the native air conditioning compressor and deactivating the fans 112 when an ambient air exchange is insufficient to provide the temperature range suitable for equipment within the enclosure. Since the DAC cooling replaces the air volume, the controller 162 is configured for operating a vent 164, baffle or louvered closure for allowing an influx of the ambient outside air into the enclosure 141.

FIGS. 4A-4B shows a door mounting of the device of FIGS. 1-2D. The enclosure 141 is often compact, and may not even afford entry access to an average adult. Such “walk-up” enclosures 141 provide merely a door for access to the equipment within the enclosure. Referring to FIGS. 4A and 4B, the cabinet 100 may be configured for mounting on a door 170 to the enclosure 141, where the enclosure is a walk-up enclosure, and an internal depth of the cabinet and device into the enclosure is non-interfering with equipment therein. FIG. 4A shows an exterior view of a door 170 mounting, and FIG. 4B shows the interior view of the door 170. The cabinet 100 is configured for mounting on the door 170 or wall of the enclosure, such that the cabinet 100 forms a fixed, non-moveable engagement with the wall. The hinged surface 114 pivots from the interior side, and may reside behind a safety cover 115. The benefit of having the hinged surface 114 for filter access on the interior side allows cabinet 100 to be completely weatherproof on the exterior with no moving or separable surfaces having gaskets or resilient sealing surfaces which can wear out and be prone to leaks.

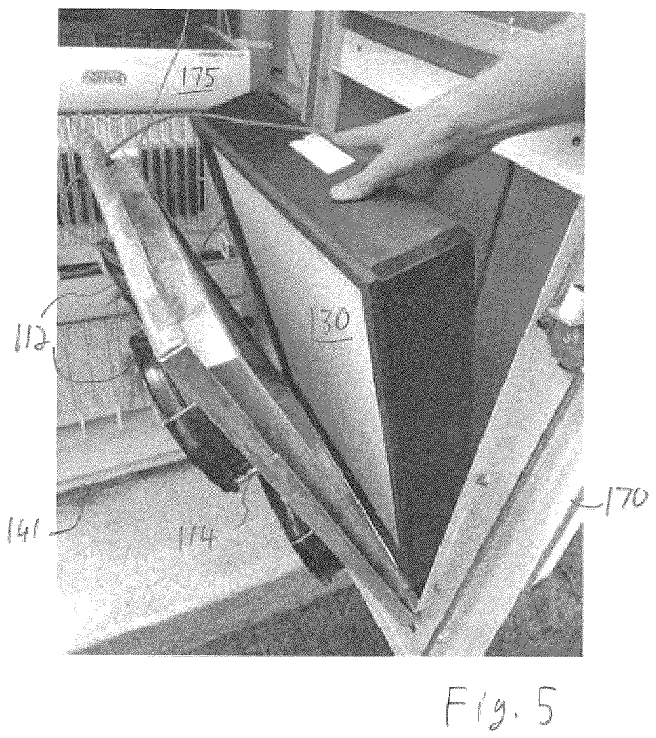

FIG. 5 shows servicing of the device of FIGS. 1-4B in a door mount context. Referring to FIGS. 1-5, in the door 170 mount, walk up arrangement, the cabinet 100 meets an exterior surface of the door 170 of the enclosure 141, Upon opening the door 170 at least 90°, the hinged surface opens in a direction normal to the closed position (or parallel to the front of the enclosure 141). Note that the equipment 175 in the cabinet 141 is recessed just enough to accommodate the hinged surface 114 in a vertical, closed position. In the open position, there is ample space for filter 130 servicing.

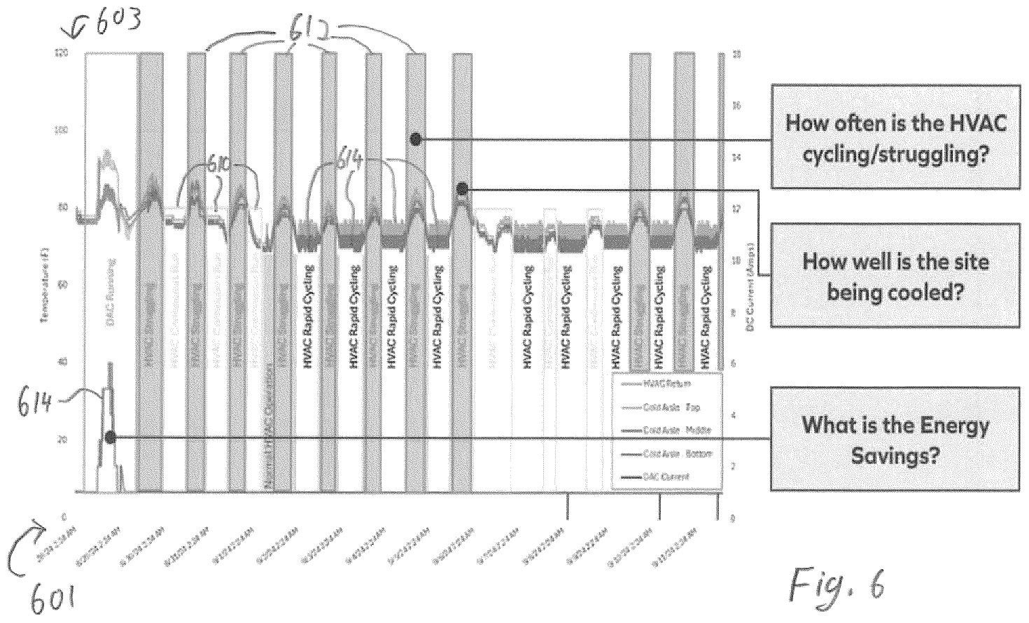

FIG. 6 shows test data from an ambient air exchange in an enclosure using the device of FIGS. 1-5. A retrofit of the device allows the DAC to supplement the compressor driven AC cooling but at a lower current draw and thus less expensive operation, as disclosed in the issued patent cited above. When the DAC is set up using the controller 162 as a primary thermal cooling solution with HVACs as a backup, there is a potential to reduce the energy consumption by 90%. These significant energy savings are achievable because the DAC hybrid approach only requires 250 watts of power, compared to around 1.5 kilowatts needed for a traditional HVAC unit. Furthermore, fewer DAC units are needed for multiple native HVAC units. With the DAC in operation primarily versus traditional HVAC, the HVAC unit(s) operate less frequently and for shorter durations, thereby greatly improving the lifespan and reliability of the HVAC. Near residential areas, this reduces nuisance compressor and fan noise. This leads to a significant decrease in the need for expensive site visits and replacement parts, minimizing the likelihood of costly early replacements of the HVAC unit(s).

FIG. 6 depicts an example dataset captured during a trial of the DAC controller, which provides key insights into environmental conditions, HVAC and DAC behavior, and power consumption. Referring to FIG. 6, daily increments along axis 601 show the temperatures 603 in the enclosure at several points. Daily increments commencing around 2:30 am show several continuous runs 610 through mid day, when daytime temperatures would tend to peak. Periods of HVAC struggling 612 are shown, and/or rapid cycling 614 as the HVAC attempts to accommodate daytime heat. DAC operation and current draw 614 promotes lower operating costs, while imposing only slightly higher enclosure temperatures.

While the system and methods defined herein have been particularly shown and described with references to embodiments thereof, it will be understood by those skilled in the art that various changes in form and details may be made therein without departing from the scope of the invention encompassed by the appended claims.

What is claimed is:

1. In a machine room enclosure for housing environmentally sensitive electronic equipment, an enclosure device for encapsulating an ambient air exchange apparatus through an exterior surface of the enclosure which exchanges ambient air with the machine room interior for controlling the temperature of the machine room, comprising:
a cabinet, the cabinet having a weathertight exterior;
a flange around a perimeter of the cabinet;
at least one fan attached to a hinged surface, the hinged surface adapted to pivot outward for access to a filter between the fan and an exterior air input passage;
a downward facing air inlet in communication with the input air passage; and
a self-aligning hinge along an edge of the hinged surface, the self-aligning hinge
adapted to support the hinged surface for filter access when in an open position, and
adapted to engage the hinged surface in a sealing engagement with the cabinet when in a closed position.

2. The device of claim 1 wherein the self-aligning hinge forms a pivoting engagement of the hinged surface with the cabinet along a lower edge of the hinged surface, and further includes a protrusion, the protrusion forming an interference fit with the cabinet when the hinged surface is in the open position.

3. The device of claim 1 wherein the flange is configured for forming a weatherproof seal with the exterior surface of the enclosure.

4. The device of claim 1 wherein the cabinet maintains a weathertight engagement with the enclosure according to a NEMA-4 criteria.

5. The device of claim 1 wherein the cabinet further comprises:
an air outlet formed from a passage through the enclosure for passage of an airflow from an interior of the enclosure to an ambient environment; and
at least one baffle configured for preventing water infiltration while permitting air exhaust from the enclosure.

6. The device of claim 1 further comprising a direct air control (DAC) circuit, the DAC circuit configured for temperature based operation of the fan based on a temperature difference between ambient air outside the enclosure and machine room air within the enclosure.

7. The device of claim 1 wherein the cabinet is configured for mounting on a door to the enclosure, the enclosure being a walk-up enclosure, and an internal depth of the cabinet into the enclosure is non-interfering with equipment therein.

8. The device of claim 1 wherein the cabinet is configured for mounting on a wall of the enclosure, the cabinet forming a fixed, non-moveable engagement with the wall.

9. The device of claim 1 further comprising a controller, the controller configured for activating the fans for exchanging ambient outside air with an air volume in the enclosure based on a temperature of the ambient outside air being cooler than an interior of the enclosure.

10. The device of claim 1 further comprising a controller, the controller configured for activating the fans for exchanging ambient outside air with an air volume in the enclosure based on a temperature of the ambient outside air being cooler than an interior of the enclosure.

11. The device of claim 9 further comprising an HVAC (Heating Ventilation Air Conditioning) interface, the HVAC interface responsive to the controller for:
deactivating a native air conditioning compressor when a temperature difference between the ambient outside air with an air volume in the enclosure provides a temperature range suitable for equipment within the enclosure; and
activating the native air conditioning compressor and deactivating the fans when an ambient air exchange is insufficient to provide the temperature range suitable for equipment within the enclosure.

12. The device of claim 9 wherein the controller is configured for operating a vent for allowing an influx of the ambient outside air into the enclosure.
